(19) United States
(12) Patent Application Publication
(10) Pub. No.: US 2023/0421044 A1
(43) Pub. Date: Dec. 28, 2023

(54) SWITCH DRIVING CIRCUIT, POWER SUPPLY CONTROL DEVICE, AND SWITCHING POWER SUPPLY

(71) Applicant: Rohm Co., Ltd., Kyoto (JP)

(72) Inventor: Yoshinori SATO, Kyoto (JP)

(21) Appl. No.: 18/326,390

(22) Filed: May 31, 2023

(30) Foreign Application Priority Data
Jun. 27, 2022 (JP) 2022-102348

(51) Int. Cl. H02M 1/08; H02M 3/335

(52) U.S. Cl. CPC H02M 1/08; H02M 3/33523

(57) ABSTRACT

A switch driving circuit includes a sink current source and a sink current adjustment unit. In turning off an N-channel type switch element, the sink current source extracts a sink current from a control end of the switch element so that a drive voltage to be applied to the control end of the switch element is decreased. While the drive voltage is being decreased, the sink current adjustment unit adjusts a current value of the sink current so that the higher the drive voltage, the larger the current value of the sink current, and the lower the drive voltage, the smaller the current value of the sink current.

### CROSS-REFERENCE TO RELATED APPLICATIONS

This application is based on the following Japanese patent application, the contents of which are incorporated herein by reference.

(1) Japanese Patent Application No. 2022-102348 (filed on Jun. 27, 2022)

### BACKGROUND OF THE DISCLOSURE

### 1. Field of the Disclosure

The present disclosure relates to a switch driving circuit, a power supply control device, and a switching power supply.

### 2. Description of Related Art

Switching power supplies are mounted in a variety of applications.

As an example of the prior art related to the above, Patent Literature 1 (Japanese Unexamined Patent Application Publication No. 2022-65435) can be cited.

Such conventional switching power supplies, however, leave room for consideration of noise reduction.

### SUMMARY OF THE DISCLOSURE

For example, a switch driving circuit disclosed herein includes a sink current source configured to, in turning off an N-channel type switch element, extract a sink current from a control end of the switch element so that a drive voltage to be applied to the control end of the switch element is decreased, and a sink current adjustment unit configured to, while the drive voltage is being decreased, adjust a current value of the sink current so that the higher the drive voltage, the larger the current value of the sink current, and the lower the drive voltage, the smaller the current value of the sink current.

Other features, elements, steps, advantages, and characteristics will become more apparent from the following description of embodiments for carrying out the disclosure and the appended drawings related to the embodiments.

### BRIEF DESCRIPTION OF THE DRAWINGS

FIG. 1 is a view showing an overall configuration of a switching power supply.

FIG. 2 is a view showing a configuration example of a semiconductor device.

FIG. 3 is a view showing an example of a turn-off behavior.

FIG. 4 is a view showing an example of output feedback control.

FIG. 5 is a view showing a first configuration example of a switch driving circuit.

FIG. 6 is a view showing an example of a sink current adjustment operation.

FIG. 7 is a view showing a second configuration example of the switch driving circuit.

### DETAILED DESCRIPTION OF PREFERRED EMBODIMENTS

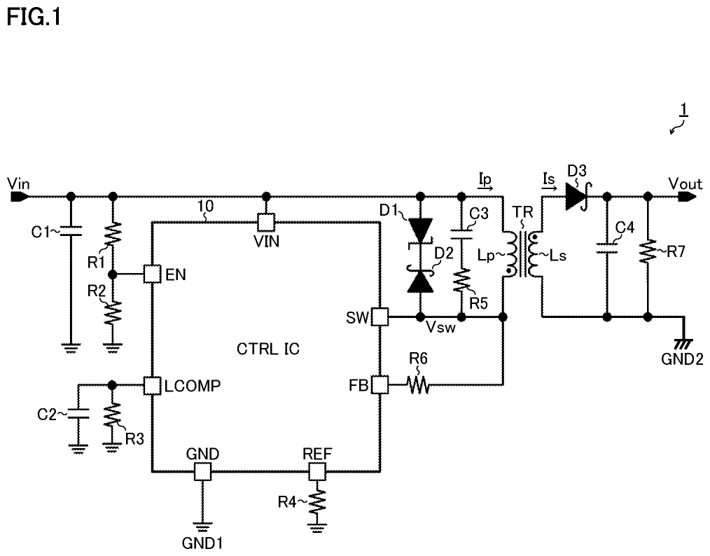

FIG. 1 is a view showing an overall configuration of a switching power supply. A switching power supply 1 of this configuration example is formed of an insulated DC/DC converter (a so-called flyback power supply) that, while providing electrical insulation between a primary circuit system (a GND1 system) and a secondary circuit system (a GND 2 system), converts a direct-current input voltage Vin supplied to the primary circuit system into a direct-current output voltage Vout having a desired value and supplies the direct-current output voltage Vout to the secondary circuit system.

Examples of an application in which the switching power supply 1 is mounted can include in-vehicle equipment (for example, an electric compressor and a main inverter), consumer appliances, industrial machines, and so on.

Referring to this figure, the switching power supply 1 includes a semiconductor device 10 and various discrete components (capacitors C1 to C4, diodes D1 to D3, resistors R1 to R7, and a transformer TR) externally connected to the semiconductor device 10.

The diode D1 may be formed of a Zener diode. The diodes D2 and D3 each may be formed of a Schottky barrier diode.

The transformer TR includes a primary winding Lp (having a number Np of turns) and a secondary winding Ls (having a number Ns of turns) that are magnetically coupled to each other while providing electrical insulation between the primary circuit system and the secondary circuit system. The numbers Np and Ns of turns could be arbitrarily adjusted so that a desired value of the direct-current output voltage Vout (=Vin×(Ns/Np)×(Ton/Toff), where Ton and Toff indicate an on-period and an off-period of an after-mentioned switch element 11, respectively) can be obtained. For example, the larger the number Np of turns or the smaller the number Ns of turns, the lower the direct-current output voltage Vout, whereas the smaller the number Np of turns or the larger the number Ns of turns, the higher the direct-current output voltage Vout.

In a case where an alternating-current input voltage Vac is supplied to the switching power supply 1, a rectifying circuit (such as a diode bridge) that convers the alternating-current input voltage Vac into the direct-current input voltage Vin could be provided to precede the switching power supply 1.

The semiconductor device 10 is a so-called power supply control IC and is provided, in the primary circuit system, as a main control subject of the switching power supply 1. The semiconductor device 10 includes a plurality of external terminals (referring to this figure, a power supply terminal VIN, a switch terminal SW, a feedback terminal FB, an enable terminal EN, a load compensation terminal LCOMP, a reference terminal REF, and a ground terminal GND) as means for establishing electrical connection with an exterior of the device.

Needless to say, in the semiconductor device 10, external terminals other than the above-described terminals may be appropriately provided as required. An internal configuration of the semiconductor device 10 will be described later.

A description is given of external connection of the semiconductor device 10. The power supply terminal VIN of the semiconductor device 10, an anode of the diode D1, first ends of the capacitors C1 and C3, a first end of the resistor R1, and a first end (a winding ending end) of the primary winding Lp of the transformer TR are all connected to an application end of the direct-current input voltage Vin. A second end of the resistor R1 and a first end of the resistor R2 are both connected to the enable terminal EN of the semiconductor device 10. Second ends of the capacitor C1 and the resistor R2 are both connected to a ground end GND1 of the primary circuit system.

A cathode of the diode D1 is connected to a cathode of the diode D2. A second end of the capacitor C3 is connected to a first end of the resistor R5. A first end of the resistor R6 is connected to the feedback terminal FB of the semiconductor device 10. An anode of the diode D2, second ends of the resistors R5 and R6, and a second end (a winding starting end) of the primary winding Lp of the transformer TR are all connected to the switch terminal SW of the semiconductor device 10.

The diodes D1 and D2, the capacitor C3, and the resistor R5 connected in this manner constitute a snubber circuit (a type of clamper circuit) for suppressing a surge voltage generated when a primary current Ip flowing through the primary winding Lp of the transformer TR is interrupted.

The load compensation terminal LCOMP of the semiconductor device 10 is connected to first ends of the capacitor C2 and the resistor R3. The reference terminal REF of the semiconductor device 10 is connected to a first end of the resistor R4. The ground terminal GND of the semiconductor device 10, a second end of the capacitor C2, and second ends of the resistors R3 and R4 are all connected to the ground end GND1.

A first end (a winding staring end) of the secondary winding Ls of the transformer TR is connected to an anode of the diode D3. A cathode of the diode D3 and first ends of the capacitor C4 and the resistor R7 are all connected to an application end of the direct-current output voltage Vout. A second end (a winding ending end) of the secondary winding Ls of the transformer TR and second ends of the capacitor C4 and the resistor R7 are all connected to a ground end GND2 of the secondary circuit system.

The diode D3 and the capacitor C4 connected in this manner constitute a rectifying and smoothing circuit for generating the direct-current output voltage Vout by rectifying and smoothing an induced voltage appearing in the secondary winding Ls of the transformer TR.

<Semiconductor Device>

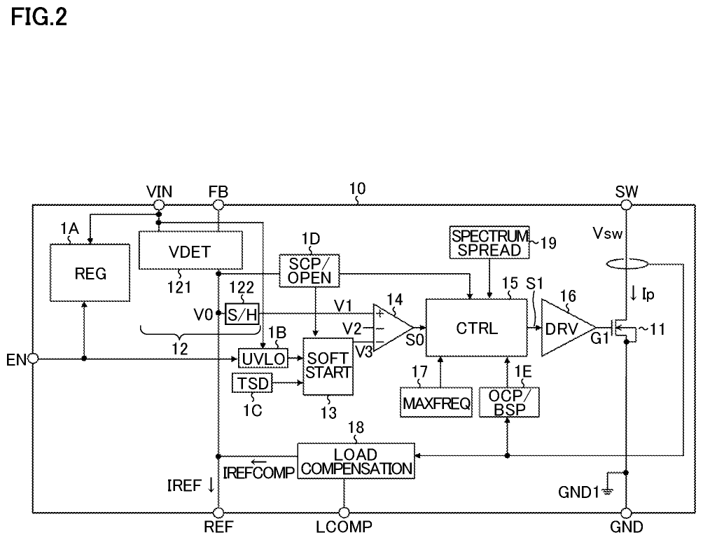

FIG. 2 is a view showing a configuration example of the semiconductor device 10. The semiconductor device 10 of this configuration example is configured by integration of the switch element 11, a feedback voltage generation circuit 12, a soft start circuit 13, a comparator 14, a controller 15, a switch driving circuit 16, a maximum frequency setting circuit 17, a load compensation circuit 18, a spectrum spreading circuit 19, an internal regulator 1A, a low input protection circuit 1B, an overheat protection circuit 1C, a short-circuit/open protection circuit 1D, and an overcurrent/power supply fault protection circuit 1E.

The switch element 11 opens/closes, in accordance with a gate drive signal G1 (corresponding to a drive voltage), a current path extending from the application end of the direct-current input voltage Vin to the ground end GND1 via the primary winding Lp of the transformer TR, thus turning on/off the primary current Ip flowing through the primary winding Lp.

In this figure, an NMOSFET (N-channel type metal oxide semiconductor field effect transistor) is used as an example of the switch element 11. In this case, a drain of the switch element 11 is connected to the switch terminal SW (and hence the second end [the winding starting end] of the primary winding Lp of the transformer TR). A source of the switch element 11, on the other hand, is connected to the ground terminal GND. The switch element 11 is brought to an on-state when the gate drive signal G1 is at a high level and to an off-state when the gate drive signal G1 is at a low level.

Furthermore, a GaN device or an SiC device may be used as the switch element 11.

In the off-period Toff of the switch element 11, the feedback voltage generation circuit 12 performs sampling of a terminal voltage of the feedback terminal FB (and hence a switch voltage Vsw appearing at the drain of the switch element 11) so as to generate a feedback voltage V1. Referring to this figure, the feedback voltage generation circuit 12 includes a voltage detection circuit 121 and a sample/hold circuit 122.

The voltage detection circuit 121 causes a monitor current IREF depending on an inter-terminal voltage (=Vin−Vsw) between the power supply terminal VIN and the feedback terminal FB to flow to the reference terminal REF so as to generate a monitor voltage V0 (=IREF×R4). The switch voltage Vsw obtained in the off-period Toff of the switch element 11 includes a flyback voltage of the transformer TR (and hence information on the direct-current output voltage Vout). This makes it possible, by monitoring the switch voltage Vsw, to perform output feedback control with the primary circuit system alone without using a photocoupler or the like.

The sample/hold circuit 122 performs sampling of the monitor voltage V0 at a predetermined timing so as to generate the feedback voltage V1.

The soft start circuit 13 generates a soft start voltage V3 that moderately increases from 0V at startup of the semiconductor device 10. At a point in time when any one of low input protection, overheat protection, and short-circuit/open protection is enabled, the soft start circuit 13 resets the soft start voltage V3 to 0V.

The comparator 14 makes a comparison between the feedback voltage V1 inputted to a non-inverted input end (+) thereof and a lower one of a reference voltage V2 inputted to one of two inverted input ends (−) thereof and the soft start voltage V3 inputted to the other of the two inverted input ends (−) thereof so as to generate a comparison signal S0. The reference voltage V2 may have, for example, a slope waveform obtained by dulling a pulse signal. The comparison signal S0 becomes high in level when the feedback voltage V1 is higher than the reference voltage V2 and becomes low in level when the feedback voltage V1 is lower than the reference voltage V2.

The controller 15 generates a gate control signal S1 for performing on/off control of the switch element 11 in accordance with the comparison signal S0. For example, the controller determines an on-timing of the switch element 11 by using, as a trigger, a pulse edge (for example, a falling edge) of the comparison signal S0. Furthermore, the controller 15 determines an off-timing of the switch element 11 by using, as a trigger, the fact that a predetermined period of time as the on-period Ton has elapsed since turn-on of the switch element 11. The controller also has a function of forcibly bringing the switch element 11 to the off-state upon detecting any of various abnormalities (for example, upon detecting a short-circuit/open abnormality or an overcurrent/power supply fault abnormality).

The switch driving circuit 16 generates, in accordance with the gate control signal S1, the gate drive signal G1 for the switch element 11. For example, when the gate control signal S1 is at a low level, the switch driving circuit 16 sets the gate drive signal G1 to the high level so as to bring the switch element 11 to the on-state. Furthermore, when the gate control signal S1 is at a high level, the switch driving circuit 16 sets the gate drive signal G1 to the low level so as to bring the switch element 11 to the off-state.

The maximum frequency setting circuit 17 controls the controller 15 to set a maximum value of a switching frequency fsw (=1/Tsw=1/(Ton+Toff)).

The load compensation circuit 18 generates a correction current IREFCOMP depending on the primary current Ip flowing through the switch element 11 (and hence the primary winding Lp of the transformer TR) and obtains a sum of the correction current IREFCOMP and the monitor current IREF so as to compensate for a change in forward drop voltage Vf generated in the diode D3. The correction current IREFCOMP can be arbitrarily adjusted by the resistor R3 and the capacitor C2 externally connected to the load compensation terminal LCOMP.

The spectrum spreading circuit 19 controls the controller 15 to perform spectrum spreading of the switching frequency fsw in a periodic or random manner.

The internal regulator 1A generates an internal power supply voltage Vreg having a predetermined value from the direct-current input voltage Vin applied to the power supply terminal VIN. For example, the internal regulator 1A is brought to an enable state when the enable terminal EN is at a high level and to a disable state when the enable terminal EN is at a low level.

The low input protection circuit 1B detects a low input state (a so-called UVLO [under-voltage locked out] state) of the direct-current input voltage Vin applied to the power supply terminal VIN and outputs a result of the detection to the soft start circuit 13. For example, the low input protection circuit 1B is brought to an enable state when the enable terminal EN is at the high level and to a disable state when the enable terminal EN is at the low level.

The overheat protection circuit 1C detects an overheat state of the semiconductor device 10 (the switch element 11 in particular) and outputs a result of the detection to the soft start circuit 13.

The short-circuit/open protection circuit 1D monitors the monitor voltage V0 applied to the reference terminal REF so as to detect a short-circuit/open abnormality of the reference terminal REF and outputs a result of the detection to each of the soft start circuit 13 and the controller 15.

The overcurrent/power supply fault protection circuit 1E monitors the primary current Ip flowing through the switch element 11 (and hence the primary winding Lp of the transformer TR) so as to detect an overcurrent state of the primary current Ip or a power supply fault state of the switch terminal SW and outputs a result of the detection to the controller 15.

Among various functional blocks described above, at least the feedback voltage generation circuit 12, the comparator 14, and the controller 15 may be understood to be constituent elements of a feedback control circuit that controls the switch driving circuit 16 in accordance with the feedback voltage V1.

<Basic Operation>

A brief description is given of a basic operation of the switching power supply 1. During the on-period Ton of the switch element 11, the primary current Ip directed to the ground end GND1 flows from the application end of the direct-current input voltage Vin via the primary winding Lp and the switch element 11. Accordingly, electric energy is stored in the primary winding Lp.

On the other hand, during the off-period Toff of the switch element 11, an induced voltage is generated in the secondary winding Ls magnetically coupled to the primary winding Lp, and thus a secondary current Is directed to the ground end GND2 flows from the secondary winding Ls via the diode D3 and the capacitor C4. At this time, there is outputted the direct-current output voltage Vout obtained by rectifying and smoothing the induced voltage in the secondary winding Ls.

Also from this time on, the switch element 11 is turned on/off, and thus a switching output operation similar to the above-described operation is repeatedly performed.

As described above, according to the switching power supply 1 of this embodiment, it is possible to generate the direct-current output voltage Vout having a desired value from the direct-current input voltage Vin while providing electrical insulation between the primary circuit system and the secondary circuit system.

<Calculation of Direct-Current Output Voltage Vout>

Meanwhile, the direct-current output voltage Vout generated in the switching power supply 1 can be calculated using Equation (1a) or (1b) below.

$$\begin{matrix}[ Mathematical Equation 1 ] & \\ V out = \frac{R 6}{R 4} \times \frac{N s}{N p} \times VINTREF - V f & ( 1 a )\end{matrix}$$

$$V out = R 6 \times \frac{N s}{N p} \times ( \frac{VINTREF}{R 4} + IREFCOMP ) - V f \qquad ( 1 b )$$

Here, Equation (1a) corresponds to a case where the load compensation terminal LCOMP is short-circuited to the ground end GND1 (namely, a case where IREFCOMP=0). On the other hand, Equation (1b) corresponds to a case where the forward drop voltage Vf in the diode D3 is compensated for by using the load compensation terminal LCOMP. Furthermore, a symbol VINTREF used in both of these equations indicates a reference voltage (for example, 0.54 V) set inside the semiconductor device 10.

Examples of factors causing an error in the above-described direct-current output voltage Vout include, in addition to variations in resistance ratio (R6/R4) and in winding ratio (Ns/Np), a change in the forward drop voltage Vf in the diode D3 (=an error attributable to a temperature and a load current). Furthermore, under a light load condition of the switching power supply 1, a surge voltage generated in the secondary winding Ls of the transformer TR is charged in the capacitor C4, and this may lead to an increase in the direct-current output voltage Vout. Such an increase in the direct-current output voltage Vout can be reduced by increasing a capacitance of the capacitor C4 or additionally providing an output resistor.

<Turn-Off Behavior>

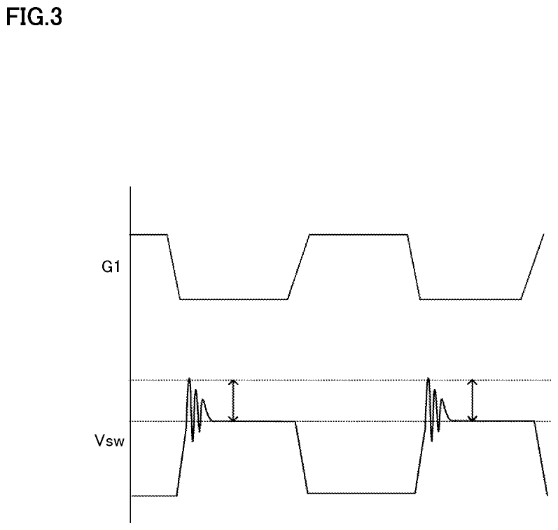

FIG. 3 is a view showing an example of a turn-off behavior of the switch element 11, in which the gate drive signal G1 and the switch voltage Vsw are depicted in order from the top. As shown in this figure, at a timing when the gate drive signal G1 falls from the high level to the low level so that the switch element 11 is switched from the on-state to the off-state, namely, a timing when the switch voltage Vsw rises from a low level to a high level, ringing (a surge) occurs in the switch voltage Vsw.

<Output Feedback Control>

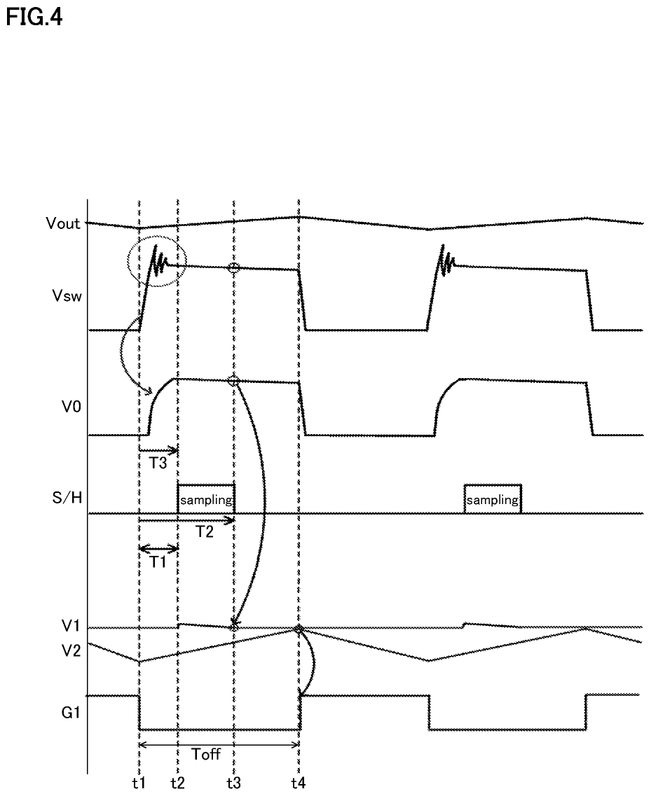

FIG. 4 is a view showing an example of output feedback control performed by the semiconductor device 10, in which the direct-current output voltage Vout, the switch voltage Vsw, the monitor voltage V0, an operation state of the sample/hold circuit 122, the feedback voltage V1, the reference voltage V2, and the gate drive signal G1 are depicted in order from the top.

At time t1, the gate drive signal G1 is caused to fall from the high level to the low level, and thus the switch element 11 is switched from the on-state to the off-state. As a result, the switch voltage Vsw increases from the low level to the high level. At this time, the direct-current output voltage Vout turns from a decrease to an increase.

In the off-period Toff (=times t1 to t4) of the switch element 11, there is generated the monitor voltage V0 having a value depending on an inter-terminal voltage (=Vin−Vsw) between the power supply terminal VIN and the feedback terminal FB. The monitor voltage V0 corresponds to the flyback voltage of the transformer TR (and hence information on the direct-current output voltage Vout), which is included in the switch voltage Vsw.

Between times t2 and t3, a process of sampling/holding the monitor voltage V0 is performed to generate (update) the feedback voltage V1.

At time t4, the reference voltage V2 having a slope waveform becomes higher than the feedback voltage V1, causing the gate drive signal G1 to rise from the low level to the high level, and thus the switch element 11 is switched from the off-state to the on-state. As a result, the switch voltage Vsw decreases from the high level to the low level. At this time, the direct-current output voltage Vout turns from an increase to a decrease.

Also from time t4 on, the above-described series of steps for performing the output feedback control is repeatedly performed. As a result, the direct-current output voltage Vout is so stabilized that the feedback voltage V1 agrees with a predetermined value (for example, 0.54 V) of the reference voltage VINTREF.

Meanwhile, as shown in this figure, at the timing (=time t1) when the switch voltage Vsw rises from the low level to the high level, due to a leakage inductance of the transformer TR, ringing (a surge) occurs in the switch voltage Vsw. This behavior has also been described using FIG. 3 referred to earlier.

In order, therefore, to prevent interference with the output feedback control, preferably, in the voltage detection circuit 121, in generating the monitor voltage V0, ringing (a surge) in the switch voltage Vsw is eliminated by setting a delay duration T3 (in this figure, between times t1 and t2, for example, a maximum of 270 ns).

Furthermore, in the semiconductor device 10, in order that a stable voltage value of the monitor voltage V0 can be read by the sample/hold circuit 122, from a turn-off timing of the switch element 11 as a starting point, there are set a sampling mask period T1 (in this figure, between times t1 and t2, for example, a minimum of 150 ns) and a sampling ending duration T2 (in this figure, between time t1 and time t3, for example, a minimum of 300 ns).

In the sampling mask period T1, a process of sampling the monitor voltage V0 performed by the sample/hold circuit 122 is internally masked. In the sampling ending duration T2, a timing for ending the sampling (=a hold timing) of the monitor voltage V0 is determined. Accordingly, the process of sampling the monitor voltage V0 is carried out from when the sampling mask period T1 expires to when the sampling ending duration T2 has elapsed (in this figure, between times t2 and t3).

In a case, however, where ringing (a surge) in the switch voltage Vsw persists even after a lapse of the sampling ending duration T2, the feedback voltage V1 might not be stabilized. Under such circumstances, in the insulated switching power supply 1 that performs the output feedback control by using the primary circuit system alone, a switching behavior may become unstable, and hence the direct-current output voltage Vout may become unstable. To avoid this trouble, it is necessary that ringing (a surge) in the switch voltage Vsw be restricted to occur before the sampling ending duration T2 ends.

Furthermore, reducing EMI (electro-magnetic interference) is one of imperative issues not only with the insulated switching power supply 1 that performs the output feedback control by using the primary circuit system alone but also with switching circuits in general. Furthermore, when ringing (a surge) in the switch voltage Vsw is large, it is necessary that the switch element 11 be increased in drain-source withstand voltage so as to be able to withstand the ringing (surge).

In view of the foregoing issues, it is imperative to reduce ringing (a surge) itself in the switch voltage Vsw. The following proposes to reduce noise by using the switch driving circuit 16.

<Switch Driving Circuit (First Configuration Example)>

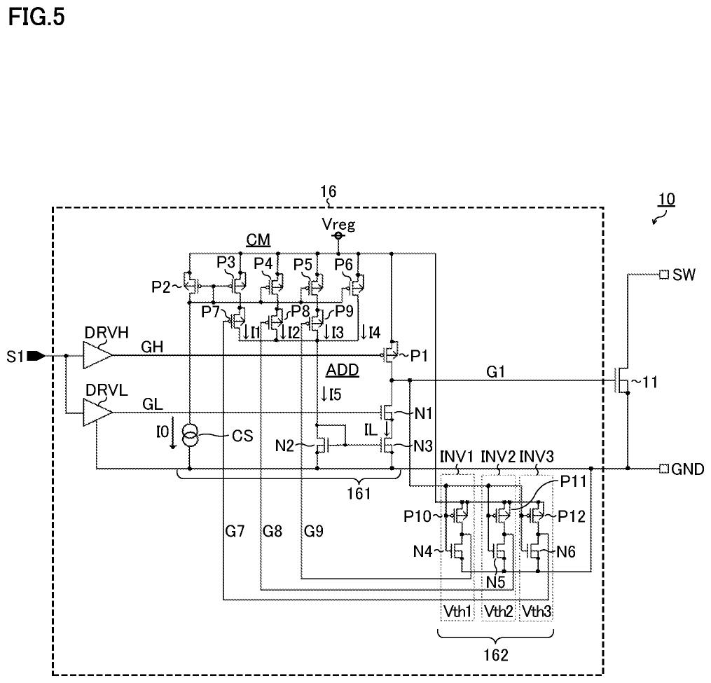

FIG. 5 is a view showing a first configuration example of the switch driving circuit 16. The switch driving circuit 16 of the first configuration example includes a reference current source CS, drivers DRVH and DRVL, transistors N1 to N6 (NMOSFETs), and transistors P1 to P12 (PMOSFETs [P-channel type MOSFETs]).

A source of the transistor P1 is connected to an application end of the internal power supply voltage Vreg. Drains of the transistors P1 and N1 are both connected to a gate of the switch element 11 (=an application end of the gate drive signal G1). A gate of the transistor P1 is connected to an output end of the driver DRVH (=an application end of an upper gate drive signal GH). A gate of the transistor N1 is connected to an output end of the driver DRVL (=an application end of a lower gate drive signal GL).

Sources of the transistors P2 to P6 are all connected to the application end of the internal power supply voltage Vreg. Gates of the transistors P2 to P6 are all connected to a drain of the transistor P2. The drain of the transistor P2 is connected to a first end of the reference current source CS. A second end of the reference current source CS is connected to the ground terminal GND.

Sources of the transistors P7 to P9 are connected to drains of the transistors P3 to P5, respectively. Gates of the transistors P7 to P9 are connected to application ends of adjustment signals G7 to G9, respectively. Drains of the transistor P6 to P9 are all connected to a drain of the transistor N2. Gates of the transistors N2 and N3 are both connected to the drain of the transistor N2. A drain of the transistor N3 is connected to a source of the transistor N1. Sources of the transistors N2 and N3 are both connected to the ground terminal GND.

Sources of the transistors P10 to P12 are all connected to the application end of the internal power supply voltage Vreg. Gates of the transistors P10 to P12 and gates of the transistors N4 to N6 are all connected to the gate of the switch element 11 (=the application end of the gate drive signal G1).

Drains of the transistors P10 and N4 are both connected to a gate of the transistor P9 (=the application end of the adjustment signal G9). Drains of the transistors P11 and N5 are both connected to a gate of the transistor P8 (=the application end of the adjustment signal G8). Drains of the transistors P12 and N6 are both connected to a gate of the transistor P7 (=the application end of the adjustment signal G7). Sources of the transistors N4 to N6 are all connected to the ground terminal GND.

In accordance with the gate control signal S1, the drivers DRVH and DRVL generate the upper gate drive signal GH and the lower gate drive signal GL, respectively. The upper gate drive signal GH and the lower gate drive signal GL both become high in level when the gate control signal S1 is at the high level and both become low in level when the gate control signal S1 is at the low level.

Accordingly, when the gate control signal S1 is at the low level, the transistor P1 is brought to an on-state, and the transistor N1 is brought to an off-state. As a result, the gate drive signal G1 becomes high in level, and thus the switch element 11 is brought to the on-state.

When, on the other hand, the gate control signal S1 is at the high level, the transistor P1 is brought to an off-state, and the transistor N1 is brought to an on-state. As a result, the gate drive signal G1 becomes low in level, and thus the switch element 11 is brought to the off-state.

Among the above-described constituent elements, the reference current source CS, the transistor P2 to P9, and the transistors N2 and N3 constitute a sink current source 161 that, in turning off the N-channel type switch element 11, extracts a sink current IL from the gate of the switch element 11 so that the gate drive signal G1 to be applied to the gate of the switch element 11 is decreased in level.

The reference current source CS generates a reference current I0 having a predetermined value.

The transistors P2 to P6 constitute a current mirror CM that generates a plurality of unit currents I1 to I4 from the reference current TO. The plurality of unit currents I1 to I4 may be equal or different in current value.

The transistors P7 to P9, N2, and N3 constitute a current addition unit ADD that obtains a sum of unit currents among the plurality of unit currents I1 to I4 as many as a number depending on the adjustment signals G7 to G9 so as to generate an added current I5 and mirrors the added current I5, thus generating the sink current IL. A capacitor may be inserted between the gates of the transistors N2 and N3 and the ground terminal GND.

When the adjustment signals G7 to G9 are all at a low level, the transistors P7 to P9 are all brought to an on-state. Accordingly, the added current I5 has a current value obtained as a total sum of current values of the unit currents I1 to I4 (=I1+I2+I3+I4). At this time, the sink current IL has its assumable maximum value.

When the adjustment signals G7 and G8 are at the low level and the adjustment signal G9 is at a high level, the transistors P7 and P8 are brought to the on-state and the transistor P9 is brought to an off state. Accordingly, the added current I5 has a current value obtained as a sum of current values of the unit currents I1, I2, and I4 (=I1+I2+I4). At this time, the sink current IL is in a state of being lowered by one step from the maximum value.

When the adjustment signal G7 is at the low level and the adjustment signals G8 and G9 are at the high level, the transistor P7 is brought to the on-state and the transistors P8 and P9 are brought to the off-state. Accordingly, the added current I5 has a current value obtained as a sum of current values of the unit currents I1 and I4 (=I1+I4). At this time, the sink current IL is in a state of being lowered by two steps from the maximum value.

When the adjustment signals G7 to G9 are all at the high level, the transistors P7 to P9 are all brought to the off-state. Accordingly, the added current I5 has a current value equal to that of the unit current I4. At this time, the sink current IL has its assumable minimum value.

Furthermore, among the above-described constituent elements, the transistors P10 to P12 and N4 to N6 constitute a sink current adjustment unit 162 that, while the gate drive signal G1 is being decreased in level, adjusts a current value of the sink current IL so that the higher the gate drive signal G1, the larger the current value of the sink current IL, and the lower the gate drive signal G1, the smaller the current value of the sink current IL.

The transistors P10 and N4 constitute an inverter INV1. The inverter INV1 has a threshold value Vth1 and has an output logic switched in accordance with the gate drive signal G1. An output signal of the inverter INV1 is outputted as the adjustment signal G9 described earlier. Accordingly, the adjustment signal G9 becomes low in level when the gate drive signal G1 has a value higher than the threshold value Vth1 and becomes high in level when the gate drive signal G1 has a value lower than the threshold value Vth1.

The transistors P11 and N5 constitute an inverter INV2. The inverter INV2 has a threshold value Vth2 different from the threshold value Vth1 (for example, Vth2<Vth1) and has an output logic switched in accordance with the gate drive signal G1. An output signal of the inverter INV2 is outputted as the adjustment signal G8 described earlier. Accordingly, the adjustment signal G8 becomes low in level when the gate drive signal G1 has a value higher than the threshold value Vth2 and becomes high in level when the gate drive signal G1 has a value lower than the threshold value Vth2.

The transistors P12 and N6 constitute an inverter INV3. The inverter INV3 has a threshold value Vth3 different from both of the threshold values Vth1 and Vth2 (for example, Vth3<Vth2) and has an output logic switched in accordance with the gate drive signal G1. An output signal of the inverter INV3 is outputted as the adjustment signal G7 described earlier. Accordingly, the adjustment signal G7 becomes low in level when the gate drive signal G1 has a value higher than the threshold value Vth3 and becomes high in level when the gate drive signal G1 has a value lower than the threshold value Vth3.

The respective threshold values Vth1 to Vth3 of the inverters INV1 to INV3 could be adjusted by, for example, arbitrarily designing a channel size (W/L [width/length]) of each of the transistors P10 to P12 and the transistors N4 to N6.

The inverters INV1 to INV3 could be formed on a single semiconductor substrate so that the mutually different threshold values Vth1 to Vth3 thereof are correlated with one another. With this configuration, even when manufacturing variations occur in each of the threshold values Vth1 to Vth3, the threshold values Vth1 to Vth3 agree with one another in terms of characteristics of the variations. This makes it unlikely that a high and low relationship among the threshold values Vth1 to Vth3 collapses.

<Sink Current Adjustment Operation>

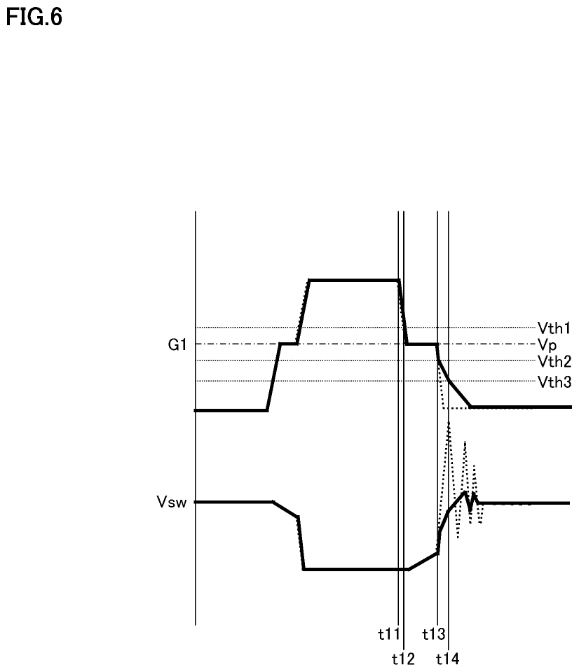

FIG. 6 is a view showing an example of a sink current adjustment operation performed in the switch driving circuit 16, in which the gate drive signal G1 and the switch voltage Vsw are depicted in order from the top. A broken line in the figure indicates a behavior before the operation is performed (=a case of a typical configuration without the sink current source 161 and the sink current adjustment unit 162), and a solid line in the figure indicates a behavior after the operation has been performed.

The threshold value Vth1 of the inverter INV1 is set to a voltage value higher than a plateau voltage Vp of the switch element 11. Furthermore, the respective threshold values Vth2 and Vth3 of the inverters INV2 and INV3 are set to voltage values lower than the plateau voltage Vp of the switch element 11.

At time t11 when the gate drive signal G1 starts to decrease in level from the high level, there is brought about a turn-off transition period of the switch element 11. At this time, the gate drive signal G1 is in a state of having a value higher than the threshold value Vth1. Accordingly, all of the adjustment signals G7 to G9 become low in level. As a result, the sink current IL is set to its assumable maximum value. That is, at a start of the turn-off transition period, the gate drive signal G1 is abruptly lowered in level at a highest decrease speed (slew rate).

At time t12 when the gate drive signal G1 falls below the threshold value Vth1, the adjustment signal G9 becomes high in level. As a result, the sink current IL is lowered by one step from its assumable maximum value. That is, a decrease speed (a slew rate) of the gate drive signal G1 is reduced by one step before the gate drive signal G1 is decreased in level to the plateau voltage Vp.

At time t13 when the gate drive signal G1 falls below the threshold value Vth2, following the adjustment signal G9, the adjustment signal G8 also becomes high in level. As a result, the sink current IL is lowered by two steps from its assumable maximum value. That is, the decrease speed (slew rate) of the gate drive signal G1 is further reduced by another step after the gate drive signal G1 has fallen below the plateau voltage Vp.

At time t14 when the gate drive signal G1 falls below the threshold value Vth3, following the adjustment signals G9 and G8, the adjustment signal G7 also becomes high in level. As a result, the sink current IL is lowered to its assumable minimum value. That is, before an end of the turn-off transition period, the gate drive signal G1 is moderately lowered in level at a lowest decrease speed (slew rate).

According to the above-described series of steps for performing the sink current adjustment operation, it becomes possible to significantly reduce ringing (a surge) in the switch voltage Vsw, which occurs when the switch element 11 is turned off. This makes it possible to detect the switch voltage Vsw with high accuracy and thus to enhance stability in performing the output feedback control.

At a point in time when lowering of the sink current IL is completed or at a lapse of a given delay duration from the point in time, the feedback voltage generation circuit 12 may start sampling of the switch voltage Vsw (and hence the monitor voltage V0). Setting such a sampling timing makes it possible to read a stable voltage value of the monitor voltage V0.

Furthermore, according to the above-described series of steps for performing the sink current adjustment operation, it is also possible to reduce EMI in the switching power supply 1 and to reduce a withstand voltage of the switch element 11. Moreover, it can also be expected to exert an effect of reducing a switching loss (particularly, a multiplication component of a reactive current and a surge voltage).

Even merely by employing a configuration in which the sink current IL having a given value is extracted in the turn-off transition period of the switch element 11, it is possible to suppress ringing (a surge) in the switch voltage Vsw. Such a configuration, however, might lead to a phenomenon in which a switching speed is decreased across the board to dull a waveform of the gate drive signal G1, causing interference with normal driving of the switch element 11.

On the other hand, according to the above-described series of steps for performing the sink current adjustment operation, in the turn-off transition period of the switch element 11, at a start of this period, the gate drive signal G1 is abruptly lowered in level as a result of the sink current IL having a large value, and then, the sink current IL is gradually reduced to reduce the decrease speed of the gate drive signal G1. Accordingly, it becomes possible to reduce ringing (a surge) in the switch voltage Vsw while suppressing a decrease in switching speed to a minimum.

<Switch Driving Circuit (Second Configuration Example)>

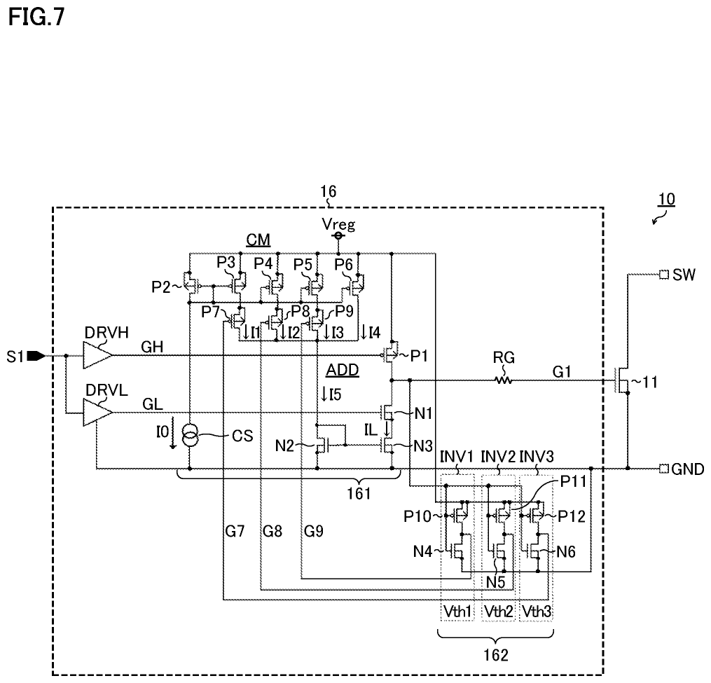

FIG. 7 is a view showing a second configuration example of the switch driving circuit 16. The switch driving circuit 16 of the second configuration example basically has the same configuration as that of the first configuration example (FIG. 5) described earlier and further includes a resistor RG.

The resistor RG is connected between the gate of the switch element 11 and the drains of the transistors P1 and N1 (corresponding to an output end of the sink current source 161). Accordingly, it becomes possible to adjust the slew rate of the gate drive signal G1 by using a current value of the sink current IL and a resistance value of the resistor RG.

### Overview

To follow is an overview of the various embodiments described thus far.

For example, the switch driving circuit disclosed herein has a configuration (a first configuration) including a sink current source configured to, in turning off an N-channel type switch element, extract a sink current from a control end of the switch element so that a drive voltage to be applied to the control end of the switch element is decreased, and a sink current adjustment unit configured to, while the drive voltage is being decreased, adjust a current value of the sink current so that the higher the drive voltage, the larger the current value of the sink current, and the lower the drive voltage, the smaller the current value of the sink current.

The switch driving circuit according to the above-described first configuration may have a configuration (a second configuration) in which the sink current source includes a reference current source configured to generate a predetermined reference current, a current mirror configured to generate a plurality of unit currents from the reference current, and a current addition unit configured to obtain a sum of unit currents among the plurality of unit currents as many as a number depending on an adjustment signal outputted from the sink current adjustment unit, thus generating the sink current.

Furthermore, the switch driving circuit according to the above-described second configuration may have a configuration (a third configuration) in which the sink current adjustment unit includes a plurality of inverters having mutually different threshold values and each configured to have an output logic switched in accordance with the drive voltage, and outputs an output signal of each of the plurality of inverters as the adjustment signal.

Furthermore, the switch driving circuit according to the above-described third configuration may have a configuration (a fourth configuration) in which the plurality of inverters is formed on a single semiconductor substrate so that the mutually different threshold values thereof are correlated with one another.

Furthermore, the switch driving circuit according to the above-described third or fourth configuration may have a configuration (a fifth configuration) in which at least one of the respective threshold values of the plurality of inverters is set to a voltage value higher than a plateau voltage of the switch element, and at least another one of the respective threshold values is set to a voltage value lower than the plateau voltage of the switch element.

Furthermore, the switch driving circuit according to any of the above-described first to fifth configurations may have a configuration (a sixth configuration) further including a resistor configured to be connected between the control end of the switch element and an output end of the sink current source.

Furthermore, for example, the power supply control device disclosed herein has a configuration (a seventh configuration) including the switch driving circuit according to any of the above-described first to sixth configurations and a feedback control circuit configured to control the switch driving circuit in accordance with a feedback voltage.

Furthermore, for example, the switching power supply disclosed herein has a configuration (an eighth configuration) including the power supply control device according to the above-described seventh configuration, in which the switching power supply turns on/off the switch element so as to generate an output voltage from an input voltage.

The switching power supply according to the above-described eighth configuration may have a configuration (a ninth configuration) in which the switching power supply is of a flyback type including a transformer, and one end of the switch element is connected to a primary winding of the transformer.

Furthermore, the switching power supply according to the above-described ninth configuration may have a configuration (a tenth configuration) in which the feedback control circuit includes a feedback voltage generation circuit configured to perform, in an off-period of the switch element, sampling of a switch voltage appearing at the one end of the switch element so as to generate the feedback voltage.

Furthermore, the switching power supply according to the above-described tenth configuration may have a configuration (an eleventh configuration) in which at a point in time when lowering of the sink current is completed or at a lapse of a given delay duration from the point in time, the feedback voltage generation circuit starts the sampling of the switch voltage.

### OTHER MODIFICATION EXAMPLES

Besides the foregoing embodiments, the various technical features disclosed herein may be modified in various ways without departing from the gist of technical creation thereof.

For example, while the foregoing embodiments are exemplarily directed to a case where switching control of the sink current IL is performed in accordance with a result of a comparison between the gate drive signal G1 and each of the threshold values Vth1 to Vth3, the switching control of the sink current IL may be performed in accordance with, for example, a duration of time that has elapsed from a start of turn-off.

Furthermore, while the foregoing embodiments are exemplarily directed to an insulated (flyback type) DC/DC converter, a non-insulated (such as step-down, step-up, or step-up/step-down) DC/DC converter or an AC/DC converter may also be used.

As discussed thus far, the foregoing embodiments are to be construed in all respects as illustrative and not limiting. The technical scope of the present disclosure is defined by the appended claims, and all changes that come within the meaning and range of equivalency of the claims may be understood to be embraced therein.

What is claimed is:

1. A switch driving circuit, comprising:
a sink current source configured to, in turning off an N-channel type switch element, extract a sink current from a control end of the switch element so that a drive voltage to be applied to the control end of the switch element is decreased; and
a sink current adjustment unit configured to, while the drive voltage is being decreased, adjust a current value of the sink current so that the higher the drive voltage, the larger the current value of the sink current, and the lower the drive voltage, the smaller the current value of the sink current.

2. The switch driving circuit according to claim 1, wherein
the sink current source includes:
a reference current source configured to generate a predetermined reference current;
a current mirror configured to generate a plurality of unit currents from the reference current; and
a current addition unit configured to obtain a sum of unit currents among the plurality of unit currents as many as a number depending on an adjustment signal outputted from the sink current adjustment unit, thus generating the sink current.

3. The switch driving circuit according to claim 2, wherein
the sink current adjustment unit includes:
a plurality of inverters having mutually different threshold values and each configured to have an output logic switched in accordance with the drive voltage, and
the sink current adjustment unit outputs an output signal of each of the plurality of inverters as the adjustment signal.

4. The switch driving circuit according to claim 3, wherein
the plurality of inverters is formed on a single semiconductor substrate so that the mutually different threshold values thereof are correlated with one another.

5. The switch driving circuit according to claim 3, wherein
at least one of the respective threshold values of the plurality of inverters is set to a voltage value higher than a plateau voltage of the switch element, and at least another one of the respective threshold values is set to a voltage value lower than the plateau voltage of the switch element.

6. The switch driving circuit according to claim 1, further comprising:
a resistor configured to be connected between the control end of the switch element and an output end of the sink current source.

7. A power supply control device, comprising:
the switch driving circuit according to claim 1; and
a feedback control circuit configured to control the switch driving circuit in accordance with a feedback voltage.

8. A switching power supply, comprising:
the power supply control device according to claim 7,
wherein
the switching power supply turns on/off the switch element so as to generate an output voltage from an input voltage.

9. The switching power supply according to claim 8, wherein
the switching power supply is of a flyback type including a transformer, and
one end of the switch element is connected to a primary winding of the transformer.

10. The switching power supply according to claim 9, wherein
the feedback control circuit includes:
a feedback voltage generation circuit configured to perform, in an off-period of the switch element, sampling of a switch voltage appearing at the one end of the switch element so as to generate the feedback voltage.

11. The switching power supply according to claim 10, wherein
the feedback voltage generation circuit includes:
a sample/hold circuit configured to start the sampling of the switch voltage at a point in time when lowering of the sink current is completed or at a lapse of a given delay duration from the point in time.
